(19) United States
(12) Patent Application Publication
(10) Pub. No.: US 2016/0111421 A1
(43) Pub. Date: Apr. 21, 2016

(54) MULTIPLE CPP FOR INCREASED SOURCE/DRAIN AREA FOR FETS INCLUDING IN A CRITICAL SPEED PATH

(71) Applicants: Mark S. RODDER, Dallas, TX (US); Rwik SENGUPTA, Austin, TX (US); Borna OBRADOVIC, Leander, TX (US)

(72) Inventors: Mark S. RODDER, Dallas, TX (US); Rwik SENGUPTA, Austin, TX (US); Borna OBRADOVIC, Leander, TX (US)

(21) Appl. No.: 14/828,509

(22) Filed: Aug. 17, 2015

Related U.S. Application Data
(60) Provisional application No. 62/066,366, filed on Oct. 21, 2014.

(51) Int. Cl. H01L 27/088; H01L 29/78; H01L 29/66; H01L 29/10

(52) U.S. Cl. CPC H01L 27/0886; H01L 29/1054; H01L 29/785; H01L 29/7849; H01L 29/66795

(57) ABSTRACT

An integrated circuit comprises at least one block comprising a first cell and a second cell. The first cell comprises a first FET formed with a first contacted poly pitch (CPP), and the second cell comprises a second FET formed with a second CPP. The first CPP is greater than the second CPP. The first FET is part of a critical-speed path, and the second FET is part of a noncritical-speed path, in which the critical-speed path operates at a faster speed than the noncritical-speed path. The first FET and the second FET each comprise a planar FET, a finFET, a gate-all-around FET or a nanosheet FET. A method for forming the integrated circuit is also disclosed.

### CROSS-REFERENCE TO RELATED APPLICATION

This application claims priority under 35 U.S.C. §120 to U.S. Provisional Patent Application Ser. No. 62/066,366, filed on Oct. 21, 2014, the contents of which are incorporated by reference in their entirety herein.

### BACKGROUND

An integrated circuit (IC), or chip, can comprise multiple circuit paths having varying circuit speeds in which the speed of some circuit paths is more critical (critical-speed paths) to overall circuit performance than other circuit paths (noncritical-speed paths). Field effect transistors (FETs) used in critical-speed paths and/or in critical-speed circuit blocks typically have a relatively high effective current I_{EFF} for a given off current I_{OFF}, generally have a higher channel strain and/or a lower parasitic resistance R_{PARA}, and/or generally have a lower parasitic capacitance C_{PARA} in comparison to FETs in noncritical-speed paths.

To control parameters, such as FET channel length variations, techniques including sidewall image transfer (SIT) or self-aligned reverse/dual patterning (which is a form of self-aligned double patterning (SADP) in which features are formed using sidewalls and space is formed using a mandrel) are used to provide spacer-defined feature formation that can be more tightly controlled. As pitches shrink, mandrels are required to be of uniform width and pitch in order to reduce FET gate length L_{G} variability, which results in a single contacted poly pitch (CPP) across an entire chip, or at least across an entire block of a chip. As used herein, the CPP of a chip is the sum of the gate length of a first FET plus the space between the gate of the first FET and the gate of a second FET that is adjacent to the first FET.

As chips scale smaller, the CPP of a chip also scales smaller. A relatively smaller CPP makes it increasingly difficult to form FETs (or critical-speed circuit blocks) that have suitable critical-speed path characteristics because the decreasing layout area for such FETs (or critical-speed circuit blocks) makes it difficult to provide a suitable power-performance-area-cost (PPAC) target for the overall design of the chip.

### SUMMARY

Exemplary embodiments provide an integrated circuit comprising high-performance FETs formed in critical-speed paths in which the high-performance FETs have a contacted poly pitch (CPP) that is greater than the CPP of FETs in noncritical-speed paths within the same block of the chip.

Exemplary embodiments provide an integrated circuit, comprising at least one block comprising a first cell and a second cell. The first cell comprises a first Field Effect Transistor (FET) formed with a first contacted poly pitch (CPP), and the second cell comprising a second FET formed with a second CPP. The first CPP is greater than the second CPP. The first FET is part of a critical-speed path, and the second FET is part of a noncritical-speed path in which the critical-speed path operates at a faster speed than the noncritical-speed path. In some exemplary embodiments, the first FET comprises a planar FET, a finFET, a gate-all-around FET or a nanosheet FET, and the second FET comprises a planar FET, a finFET, a gate-all-around FET or a nanosheet FET.

Some exemplary embodiments provide that the first FET comprises a source/drain region having a first cross-sectional area and volume, and the second FET comprises a source/drain region having a second cross-sectional area and volume, and in which the first cross-sectional area and volume are greater than the second cross-sectional area and volume.

Some exemplary embodiments provide that a gate length of the first FET is substantially the same as a gate length of the second FET.

Some exemplary embodiments provide that a channel strain of the first FET is greater than a channel strain of the second FET.

Some exemplary embodiments provide that a parasitic resistance of the first FET is less than a parasitic resistance of the second FET.

Some exemplary embodiments provide that a parasitic capacitance of the first FET is less than a parasitic capacitance of the second FET.

Exemplary embodiments provide an integrated circuit, comprising: a critical-speed circuit path in a block of the integrated circuit in which the critical-speed circuit path comprises a first Field Effect Transistor (FET) comprising a first contacted poly pitch (CPP); and a noncritical-speed circuit path in the block of the integrated circuit in which the noncritical-speed path comprises a second FET comprising a second CPP, and in which the first CPP is greater than the second CPP. In some exemplary embodiments, the first FET comprises a planar FET, a finFET, a gate-all-around FET or a nanosheet FET, and the second FET comprises a planar FET, a finFET, a gate-all-around FET or a nanosheet FET.

Some exemplary embodiments provide that the first FET comprises a source/drain region having a first cross-sectional area and volume, and the second FET comprises a source/drain region having a second cross-sectional area and volume, and in which the first cross-sectional area and volume is greater than the second cross-sectional area and volume.

Some exemplary embodiments provide that a gate length of the first FET is substantially the same as a gate length of the second FET.

Some exemplary embodiments provide that a channel strain of the first FET is greater than a channel strain of the second FET.

Some exemplary embodiments provide that a parasitic resistance of the first FET is less than a parasitic resistance of the second FET.

Some exemplary embodiments provide that a parasitic capacitance of the first FET is less than a parasitic capacitance of the second FET.

Exemplary embodiments provide a method to form Field Effect Transistors (FETs) in a block of an integrated circuit, the method comprising: forming a first FET in the block, the first FET comprising a first contacted poly pitch (CPP); and forming a second FET in the block, the second FET comprising a second CPP, in which the first CPP is greater than the second CPP.

Some exemplary embodiments provide that the first FET is part of a critical-speed path, and wherein the second FET is part of a noncritical-speed path, the critical-speed path operating at a faster speed than the noncritical-speed path.

Some exemplary embodiments provide a method to form FETs in a block of an integrated circuit further comprising forming a source/drain region for the first FET having a first cross-sectional area and volume; and forming a source/drain region for the second FET having a second cross-sectional area and volume, in which the first cross-sectional area and volume is greater than the second cross-sectional area and volume.

Some exemplary embodiments provide that a parasitic resistance of the first FET is less than a parasitic resistance of the second FET.

Some exemplary embodiments provide that a parasitic capacitance of the first FET is less than a parasitic capacitance of the second FET.

### BRIEF DESCRIPTION OF THE DRAWINGS

Example embodiments will be more clearly understood from the following detailed description taken in conjunction with the accompanying drawings. The Figures represent non-limiting, example embodiments as described herein.

FIGS. 1A and 1B respectively depict top views of a first exemplary embodiment of a finFET in a critical-speed path and, in contrast, a finFET in a noncritical-speed path on the same chip according to the subject matter disclosed herein;

FIGS. 2A and 2B respectively depict top views of a second exemplary embodiment of a finFET in a critical-speed path and, in contrast, a finFET in a noncritical-speed path on the same chip according to the subject matter disclosed herein;

FIGS. 3A and 3B respectively depict top views of a third exemplary embodiment of a finFET in a critical-speed path and in contrast a finFET in a noncritical-speed path on the same chip according to the subject matter disclosed herein;

FIG. 4 depicts an exemplary embodiment of a portion of a first chip layout according to the subject matter disclosed herein;

FIG. 5 depicts an exemplary embodiment of a portion of a second chip layout according to the subject matter disclosed herein;

FIG. 6 depicts an exemplary embodiment of a portion of a third chip layout according to the subject matter disclosed herein;

FIG. 7 depicts an exemplary embodiment of a method to form FETs in a critical-speed path and FETs in a noncritical-speed path on the same chip according to the subject matter disclosed herein;

FIGS. 8A-8H depict various stages of forming FETs in a critical-speed path and FETs in a noncritical-speed path on the same chip in accordance with exemplary embodiment of FIG. 7;

FIG. 9 depicts an electronic device that comprises one or more semiconductor devices according to exemplary embodiments disclosed herein; and

FIG. 10 depicts a memory system that comprises one or more semiconductor devices according to example embodiments disclosed herein

### DESCRIPTION OF EMBODIMENTS

The subject matter disclosed herein relates to low-power, high-performance integrated circuits (chips) comprising high-performance FETs formed in critical-speed paths in which the high-performance FETs have a contacted poly pitch (CPP) that is greater than the CPP of FETs in noncritical-speed paths within the same block of a chip. Additionally, the subject matter disclosed herein provides a beneficial power-performance-area-cost (PPAC) target for such a chip by providing an acceptable increase in A (area) in order to obtain an improvement in power-performance (PP), i.e., higher performance at the same or lower power.

Various exemplary embodiments will be described more fully hereinafter with reference to the accompanying drawings, in which some exemplary embodiments are shown. As used herein, the word “exemplary” means “serving as an example, instance, or illustration.” Any embodiment described herein as “exemplary” is not to be construed as necessarily preferred or advantageous over other embodiments. The subject matter disclosed herein may, however, be embodied in many different forms and should not be construed as limited to the exemplary embodiments set forth herein. Rather, the exemplary embodiments are provided so that this description will be thorough and complete, and will fully convey the scope of the claimed subject matter to those skilled in the art. In the drawings, the sizes and relative sizes of layers and regions may be exaggerated for clarity.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the claimed subject matter.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The subject matter disclosed herein relates to low-power, high-performance integrated circuits (chips) comprising high-performance FETs in critical-speed paths in which the high-performance FETs have a contacted poly pitch (CPP) that is greater than the CPP of FETs in noncritical-speed paths within the same block of a chip. The subject matter disclosed herein also provides a Complementary Metal Oxide Semiconductor (CMOS) fabrication technique to form high-performance FETs for critical-speed circuit paths and/or circuit blocks within a chip that are not constrained by a single CPP across the entire chip. In one exemplary embodiment, the subject matter disclosed herein provides different CPPs within the same block of a floorplan of an integrated circuit by using dummy patterns in pitch transition areas.

One aspect of the subject matter disclosed herein provides a technique to form high-performance FETs without relying solely on new channel materials and/or new substrate materials, although such new channel materials and/or new substrate materials could be used with the disclosed subject matter. Another aspect of the subject matter disclosed herein provides a technique to form high-performance FETs that do not have a substantially increased off-current I_{OFF} with a corresponding increase in power consumption. Yet another aspect of the subject matter disclosed herein provides FETs in critical-speed paths having the same or substantially the same (patterned) L_{G} as at least some FETs in noncritical-speed paths.

It should be understood that the techniques disclosed herein can be applied to any circuit path in any circuit block, if desired, regardless whether the circuit path is a critical-speed path or a noncritical-speed path.

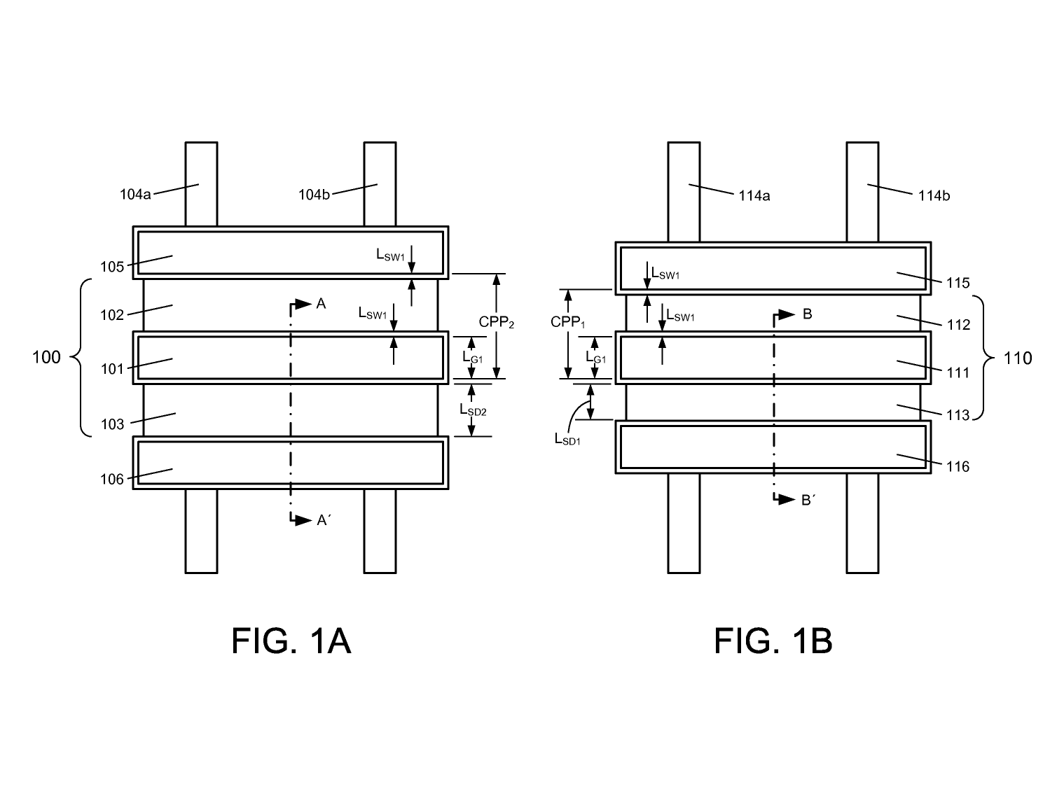

FIGS. 1A and 1B respectively depict top views of a first exemplary embodiment of a finFET 100 in a critical-speed path and, in contrast, a finFET 110 in a noncritical-speed path on the same chip according to the subject matter disclosed herein. Alternatively, finFET 100 could be in a critical-speed path and a finFET 110 could be in a noncritical-speed path in the same block of a chip.

FinFET 100 in FIG. 1A comprises a gate region 101, merged source/drain (S/D) regions 102 and 103, and fins 104a and 104b. Gate region 101 and merged S/D regions 102 and 103 are strapped between fins 104a and 104b in a well-known manner. Gate regions 105 and 106 are gates of FETs that are adjacent to finFET 100 within the critical-speed path depicted in FIG. 1A.

FinFET 110 in FIG. 1B comprises a gate region 111, merged S/D regions 112 and 113, and fins 114a and 114b. Gate region 111 and merged S/D regions 112 and 113 are strapped between fins 114a and 114b in a well-known manner. Gate regions 115 and 116 are gates of FETs that are adjacent to finFET 110 within the noncritical-speed path depicted in FIG. 1B.

In the embodiment depicted in FIGS. 1A and 1B, finFET 100 and finFET 110 have the same or substantially the same gate length L_{G1}, and the same or substantially the same sidewall length L_{SW1}. FinFET 100 differs from finFET 110 in that the CPP₂ of finFET 100 is greater than the CPP₁ of finFET 110. As used herein, the CPP of a chip (or block) is the sum of the gate length of a first FET plus the space between the gate of the first FET and the gate of a second FET that is adjacent to the first FET. Referring to FIG. 1A, CPP₂ is the sum of the gate length L_{G1} plus two times the sidewall length L_{SW1} plus the merged source/drain length L_{SD2}. In FIG. 1B, CPP₁ is the sum of the gate length L_{G1} plus two times the sidewall length L_{SW1} plus the merged source/drain length L_{SD1}. Thus, the difference between CPP₂ and CPP₁ is the length L_{SD2} of the merged S/D regions 102 and 103, which is greater than the length of L_{SD1} of merged S/D regions 112 and 113. In an alternative exemplary embodiment, finFET 100 could have a sidewall length L_{SW} that is greater than the sidewall length L_{SW1} of finFET 110.

The larger CPP₂ of finFET 100 allows for a larger S/D volume and cross-sectional area, contact area and contact volume than that provided by the CPP₁ of finFET 110. In one exemplary embodiment, the larger S/D volume of finFET 100 allows for a greater channel strain that could be produced from source/drain stressor materials than provided by the CPP₁ and S/D volume finFET 110. In another exemplary embodiment, the larger S/D volume of finFET 100 comprises a lower parasitic resistance R_{PARA} provided by the correspondingly larger source/drain contact area. The increased channel strain and/or the lower R_{PARA} provide a higher value of effective current I_{EFF} for a given off current I_{OFF}. In another exemplary embodiment, the larger CPP₂ of finFET 100 comprises a lower parasitic capacitance C_{PARA} by allowing for a larger contact-gate spacing. In still another exemplary embodiment in which the sidewall length L_{SW} of finFET 100 is greater than the sidewall length L_{SW1} of finFET 110, finFET 100 comprises a lower parasitic capacitance C_{PARA} by also allowing for a larger contact-gate spacing.

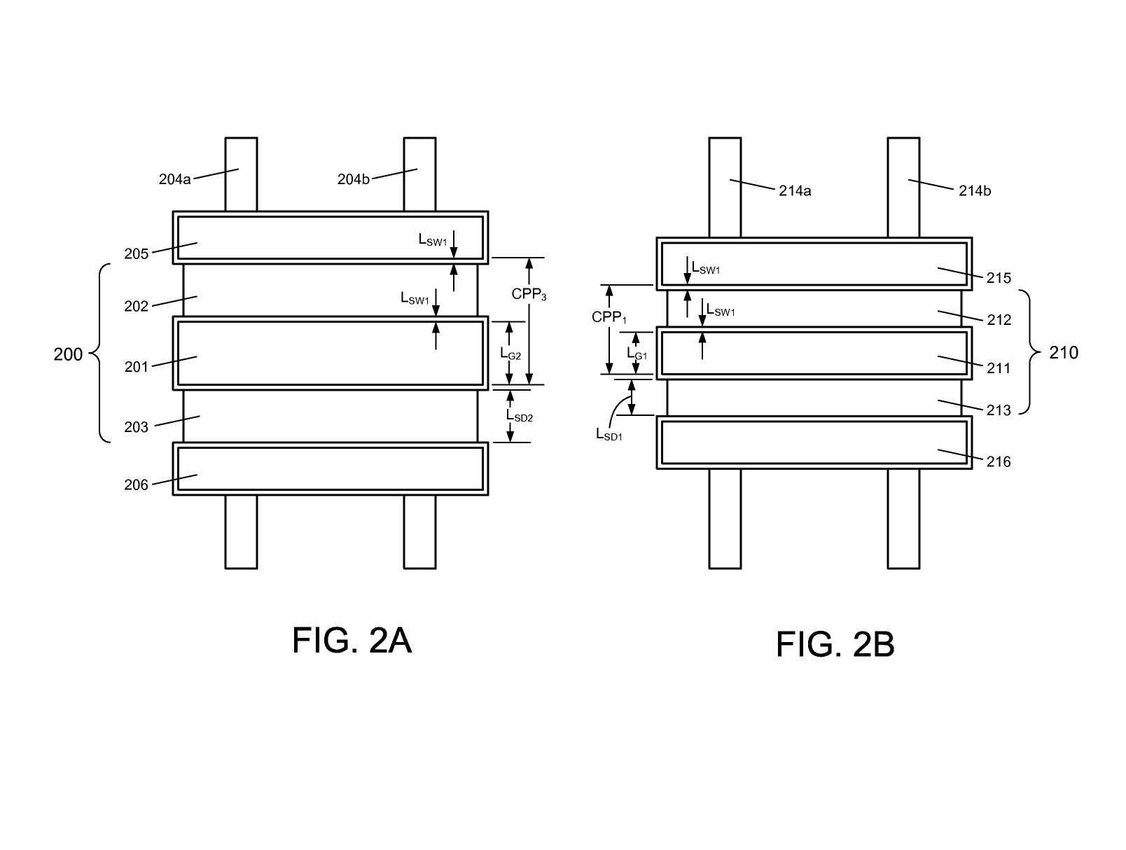

FIGS. 2A and 2B respectively depict top views of a second exemplary embodiment of a finFET 200 in a critical-speed path and, in contrast, a finFET 210 in a noncritical-speed path on the same chip according to the subject matter disclosed herein. Alternatively, finFET 200 could be in a critical-speed path and a finFET 210 could be in a noncritical-speed path in the same block of a chip.

FinFET 200 in FIG. 2A comprises a gate region 201, merged source/drain (S/D) regions 202 and 203, and fins 204a and 204b. Gate region 201 and merged S/D regions 202 and 203 are strapped between fins 204a and 204b in a well-known manner. Gate regions 205 and 206 are gates of FETs that are adjacent to finFET 200 within the critical-speed path depicted in FIG. 2A.

FinFET 210 in FIG. 2B comprises a gate region 211, merged S/D regions 212 and 213, and fins 214a and 214b. Gate region 211 and merged S/D regions 212 and 213 are strapped between fins 214a and 214b in a well-known manner. Gate regions 215 and 216 are gates of FETs that are adjacent to finFET 210 within the critical-speed path depicted in FIG. 2B.

As depicted in FIGS. 2A and 2B, finFET 200 differs from finFET 210 by having a gate length L_{G2} and a CPP₃ that are respectively greater than the gate length L_{G1} and CPP₁ of finFET 210. Thus, the larger CPP₃ for finFET 200 is the result of the gate length L_{G2}, and the source/drain length L_{SD2} of merged S/D regions 202 and 203 respectively being greater than the gate length L_{G1} and the source/drain length L_{SD1} of merged S/D regions 212 and 213. In this exemplary embodiment, sidewall length L_{SW1} is the same or substantially the same for both finFET 200 and 210.

In one exemplary embodiment, CPP₃ may be greater than CPP₂, which is depicted in FIG. 1A. Alternatively, CPP₃ may be substantially equal to CPP₂. In yet another exemplary embodiment in which CPP₃ of FIG. 2A is greater than CPP₂ of FIG. 1A, the gate length L_{G2} could substantially equal gate length L_{G1}.

Similar to CPP₂ of finFET 100 (FIG. 1A), the larger CPP₃ of finFET 200 allows for a larger S/D volume and cross-sectional area, contact area and contact volume than that provided by the CPP₁ of finFET 210. In one exemplary embodiment, the larger S/D volume of finFET 200 allows for a greater channel strain that could be produced from source/drain stressor materials than provided by the CPP₁ and S/D volume finFET 210. In another exemplary embodiment, the larger S/D volume of finFET 200 comprises a lower parasitic resistance R_{PARA} provided by the correspondingly larger source/drain contact area. The increased channel strain and/or the lower R_{PARA} provide a higher value of effective current I_{EFF} for a given off current I_{OFF}. In another exemplary embodiment, the larger CPP₃ of finFET 200 comprises a lower parasitic capacitance C_{PARA} by allowing for a larger contact-gate spacing. In still another exemplary embodiment in which the sidewall length L_{SW} of finFET 200 is greater than the sidewall length L_{SW1} of finFET 210, finFET 200 comprises a lower parasitic capacitance C_{PARA} by also allowing for a larger contact-gate spacing.

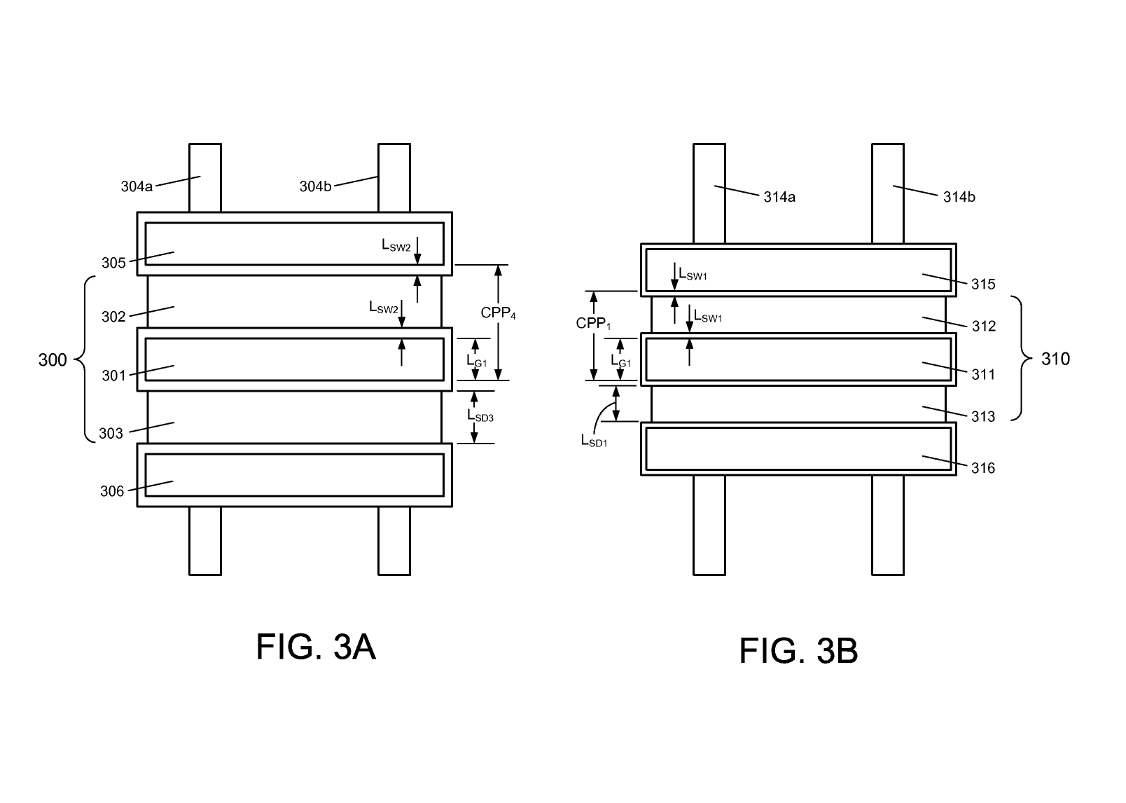

FIGS. 3A and 3B respectively depict top views of a third exemplary embodiment of a finFET 300 in a critical-speed path and in contrast a finFET 310 in a noncritical-speed path on the same chip according to the subject matter disclosed herein. Alternatively, finFET 300 could be in a critical-speed path and a finFET 310 could be in a noncritical-speed path in the same block of a chip.

FinFET 300 in FIG. 3A comprises a gate region 301, merged source/drain (S/D) regions 302 and 303, and fins 304a and 304b. Gate region 301 and merged S/D regions 302 and 303 are strapped between fins 304a and 304b in a well-known manner. Gate regions 305 and 306 are gates of FETs that are adjacent to finFET 300 within the critical-speed path depicted in FIG. 3A.

FinFET 310 in FIG. 3B comprises a gate region 311, merged S/D regions 312 and 313, and fins 314a and 314b. Gate region 311 and merged S/D regions 312 and 313 are strapped between fins 314a and 314b in a well-known manner. Gate regions 315 and 316 are gates of FETs that are adjacent to finFET 310 within the critical-speed path depicted in FIG. 3B.

As depicted in FIGS. 3A and 3B, finFET 300 and finFET 310 have the same or substantially the same gate length L_{G1}. FinFET 300 differs from finFET 310 in that the CPP₄ of finFET 300 is greater than the CPP₁ of finFET 310. The difference between CPP₄ and CPP₁ is the sidewall length L_{SW2} and the length L_{SD3} of merged S/D regions 302 and 303, which are respectively greater than the sidewall length L_{SW1} and the length of L_{SD1} of merged S/D regions 312 and 313. In one exemplary embodiment, CPP₄ may be greater than both CPP₂ depicted in FIG. 1A and CPP₃ depicted in FIG. 2A. Alternatively, CPP₄ may be equal to or substantially equal to CPP₂ and/or CPP₃.

The larger CPP₄ of finFET 300 allows for a larger S/D volume and cross-sectional area, contact area and contact volume than that provided by the CPP₁ of finFET 310. In one exemplary embodiment, the larger S/D volume of finFET 300 allows for a greater channel strain that could be produced from source/drain stressor materials than provided by the CPP₁ and S/D volume finFET 310. In another exemplary embodiment, the larger S/D volume of finFET 300 comprises a lower parasitic resistance R_{PARA} provided by the correspondingly larger source/drain contact area. The increased channel strain and/or the lower R_{PARA} provide a higher value of effective current I_{EFF} for a given off current I_{OFF}. In another exemplary embodiment, the larger CPP₄ of finFET 200 comprises a lower parasitic capacitance C_{PARA} by allowing for a larger contact-gate spacing.

Although FIGS. 1A-3B depict FETs that are configured as finFETs, it should be understood that the subject matter disclosed herein is not limited to finFETs. Alternatively, the subject matter disclosed herein is applicable to planar FETs, finFETs, gate-all-around FETs and nanosheet FETs regardless whether a FET is a p-type or an n-type FET.

Additionally, the materials used to form the channel, the source/drains and/or the contacts of FETs depicted in FIGS. 1A-3B may be the same, substantially the same or different regardless whether the FET is in a critical-speed path or block, or a noncritical-speed path or block. The materials used to form the FETs disclosed herein may, for example, include compositions comprising group III-V, group IV, group II-VI materials, or combinations thereof. One exemplary embodiment provides a first FET in a critical-speed path having a relatively larger CPP formed from a group III-V material and a second FET in a noncritical-speed path having a relatively smaller CPP formed from a group IV material.

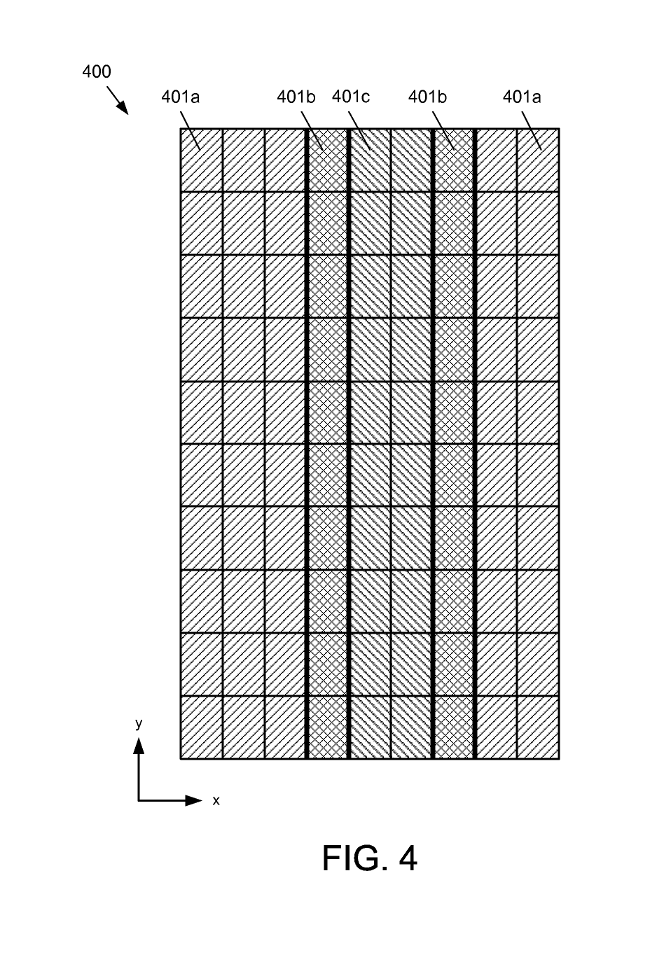

FIG. 4 depicts an exemplary embodiment of a portion of a first chip layout according to the subject matter disclosed herein. In one exemplary embodiment, the portion of chip layout depicted in FIG. 4 corresponds to a block 400. Block 400 comprises a plurality of cells 401 arranged in rows and columns In one exemplary embodiment, an area of a cell may be a few μm2, and an area of a block may be 100 μm2 to 4 mm2. As depicted in FIG. 4, rows extend in the x direction and columns extend in the y direction. Block 400 is arranged so that cells having the same or substantially the same CPP are arranged in columns Alternatively, the cells that have the same or substantially the same CPP could be arranged in rows. The arrangement of block 400 does not require bidirectional mandrels or aggressive terminations in which no or very little area is lost between CPP regions to provide high-performance FETs for critical-speed circuit paths. Additionally, by aggregating larger CPP area into a larger block size, the number of CPP transition zones is accordingly reduced, thereby making a higher transition-area penalty more tolerable without increasing block or chip area significantly. It should be understood that the arrangement of cells depicted in FIG. 4 is exemplary and other arrangements are possible.

In the exemplary embodiment depicted in FIG. 4, cells 401a comprise a first CPP. Cells 401b comprise a second CPP, and cells 401c comprise a third CPP. In one exemplary embodiment, the first CPP of cells 401 may be selected for noncritical-speed paths of cells and may correspond to, for example, CPP₁ depicted in FIGS. 1B, 2B and 3B. Cells 401b comprise CPP-transition cells, or pitch transition areas, in which the second CPP could correspond to, for example, CPP₂ of FIG. 2A. Cells 401c comprise a third CPP that has been selected for critical-speed paths and could correspond to, for example, CPP₃ of FIG. 3A. Cells 401b are positioned between cells 401a and 401c prevent pitchwalking that may be caused by the different CPP in cells 401a and 401c.

In some exemplary embodiments, cells 401b may comprise dummy cells. Alternatively, in some exemplary embodiments, cells 401b may comprise active circuit components.

In one exemplary embodiment, cells 401b comprise a first type of dummy cells comprising a standard logic cell footprint having inactive MOSFETs. Such a standard logic cell could contain features having both a small and a large CPP to allow the CPPs within the block to transition between cells 401a and 401c without adversely impacting any active gates in cells 401a and 401c, or requiring additional design margins to avoid the risk of timing-related failures in the block and/or loss of performance and power. Alternatively, a second type of dummy cell, which could be placed in a column (i.e., the y direction) from a cell 401c, could comprise mandrel terminations using dummy fins, thereby avoiding non-rectangular mandrels. The mandrel terminations preserve rectangular mandrel shapes because the gates in two different CPP regions do not line up vertically (i.e., the y direction). The dummy fins help provide a suitable environment to the active fins above and below (i.e., in the y direction) the dummy vertical cell, and also allow a fin multiple of four to be compliant with a self-aligned quadruple pitch (SAQP) process.

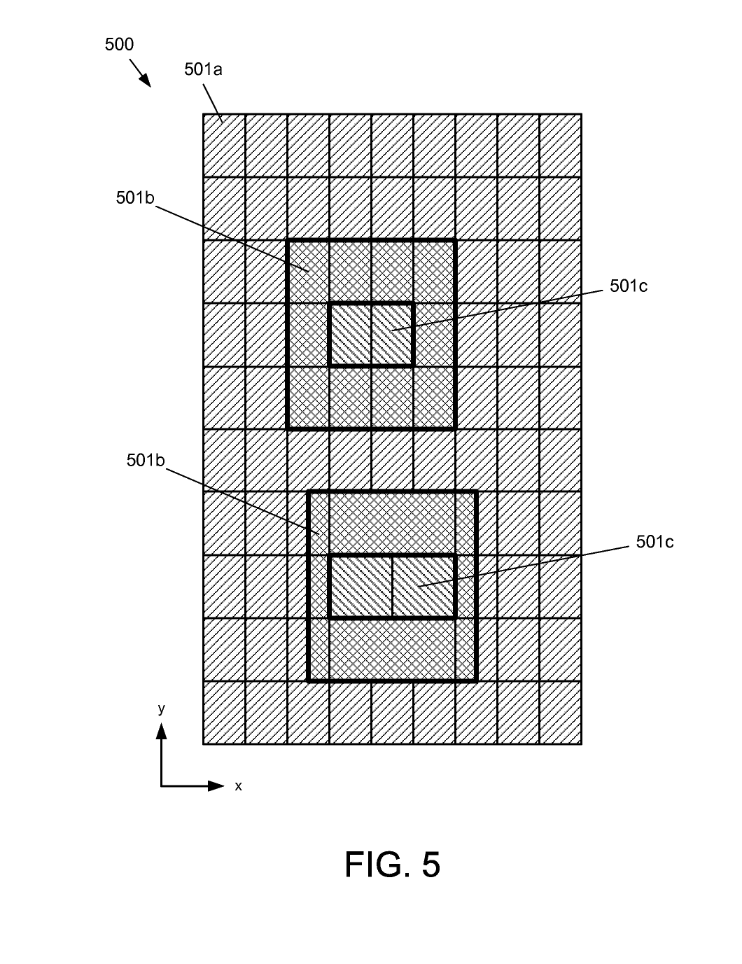

FIG. 5 depicts an exemplary embodiment of a portion of a second chip layout according to the subject matter disclosed herein. In one exemplary embodiment, the portion of chip layout depicted in FIG. 5 corresponds to a block 500. Block 500 comprises a plurality of cells 501 arranged in rows and columns As depicted in FIG. 5, rows extend in the x direction and columns extend in the y direction. Block 500 is arranged so that cells having the same or substantially the same CPP are arranged in localized areas or localized regions within block 500. Similar to the arrangement depicted in FIG. 4, block 500 does not require bidirectional mandrels or aggressive terminations to provide high-performance FETs for critical-speed circuit paths. It should also be understood that the arrangement of cells depicted in FIG. 5 is exemplary and other arrangements are possible.

In the exemplary embodiment depicted in FIG. 5, cells 501a comprise a first CPP. Cells 501b comprise a second CPP, and cells 501c comprise a third CPP. In one exemplary embodiment, the first CPP of cells 501 may be selected for noncritical-speed paths of cells and may correspond to, for example, CPP₁ depicted in FIGS. 1B, 2B and 3B. Cells 501b comprise CPP-transition cells, or pitch transition areas, in which the second CPP could correspond to, for example, CPP₂ of FIG. 2A. Cells 501c comprise a third CPP that has been selected for critical-speed paths and could correspond to, for example, CPP₃ of FIG. 3A. Cells 501b are positioned between cells 501a and 501c prevent pitchwalking that may be caused by the different CPP in cells 501a and 501c.

In some exemplary embodiments, cells 501b may comprise dummy cells of the first or second type described above. Alternatively, in some exemplary embodiments, cells 501b may comprise active circuit components.

FIG. 6 depicts an exemplary embodiment of a portion of a third chip layout according to the subject matter disclosed herein. In one exemplary embodiment, the portion of chip layout depicted in FIG. 6 corresponds to a block 600. Block 600 comprises a plurality of cells 601 arranged in columns and rows. As depicted in FIG. 6, rows extend in the x direction and columns extend in the y direction. Block 600 is arranged so that cells having the same or substantially the same CPP are arranged or grouped in areas or regions that are generally larger than the localized areas or regions depicted in FIG. 5. Similar to the arrangements depicted in FIGS. 4 and 5, block 600 does not require bidirectional mandrels or aggressive terminations to provide high-performance FETs for critical-speed circuit paths. It should also be understood that the arrangement of cells depicted in FIG. 6 is exemplary and other arrangements are possible.

In the exemplary embodiment depicted in FIG. 6, cells 601a comprise a first CPP. Cells 601b comprise a second CPP, and cells 601c comprise a third CPP. In one exemplary embodiment, the first CPP of cells 601 may be selected for noncritical-speed paths of cells and may correspond to, for example, CPP₁ depicted in FIGS. 1B, 2B and 3B. Cells 601b comprise CPP-transition cells, or pitch transition areas, in which the second CPP could correspond to, for example, CPP₂ of FIG. 2A. Cells 601c comprise a third CPP that has been selected for critical-speed paths and could correspond to, for example, CPP₃ of FIG. 3A. Cells 601b are positioned between cells 601a and 601c prevent pitchwalking that may be caused by the different CPP in cells 601a and 601c.

In some exemplary embodiments, cells 601b may comprise dummy cells of the first or second type described above. Alternatively, in some exemplary embodiments, cells 601b may comprise active circuit components.

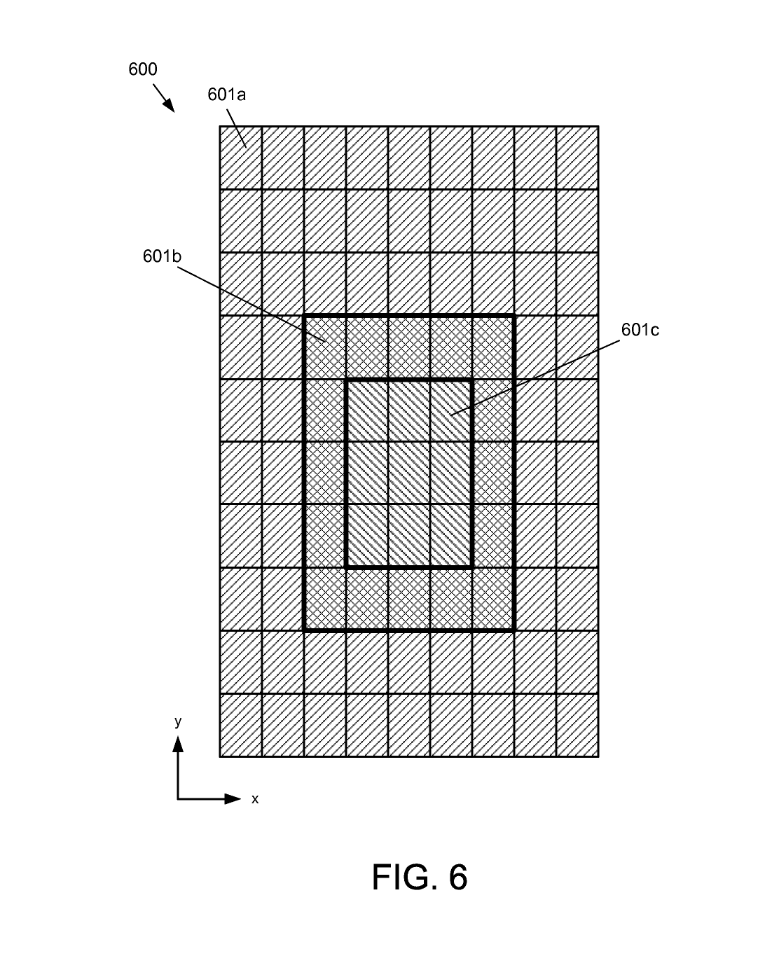

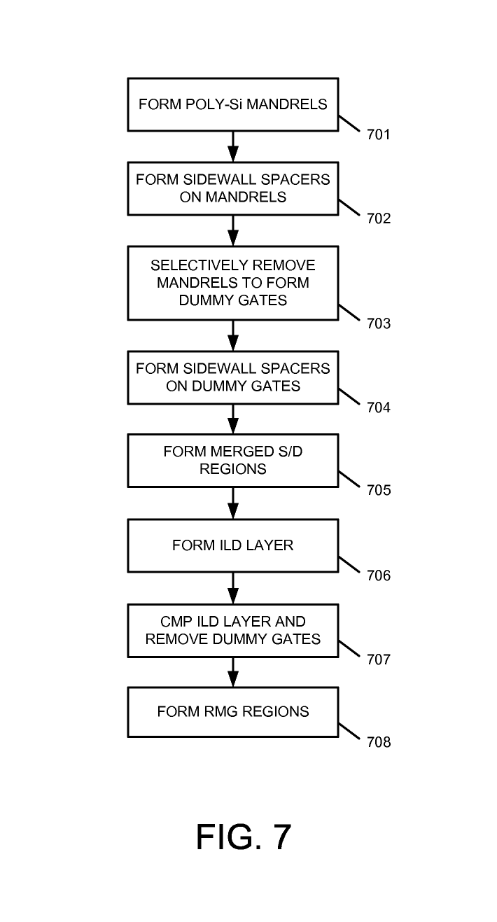

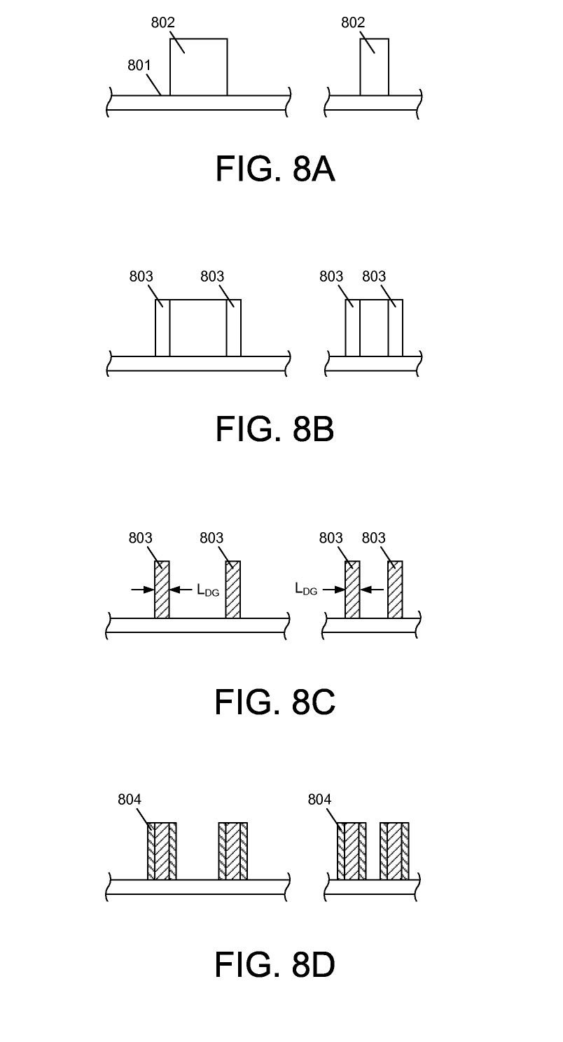

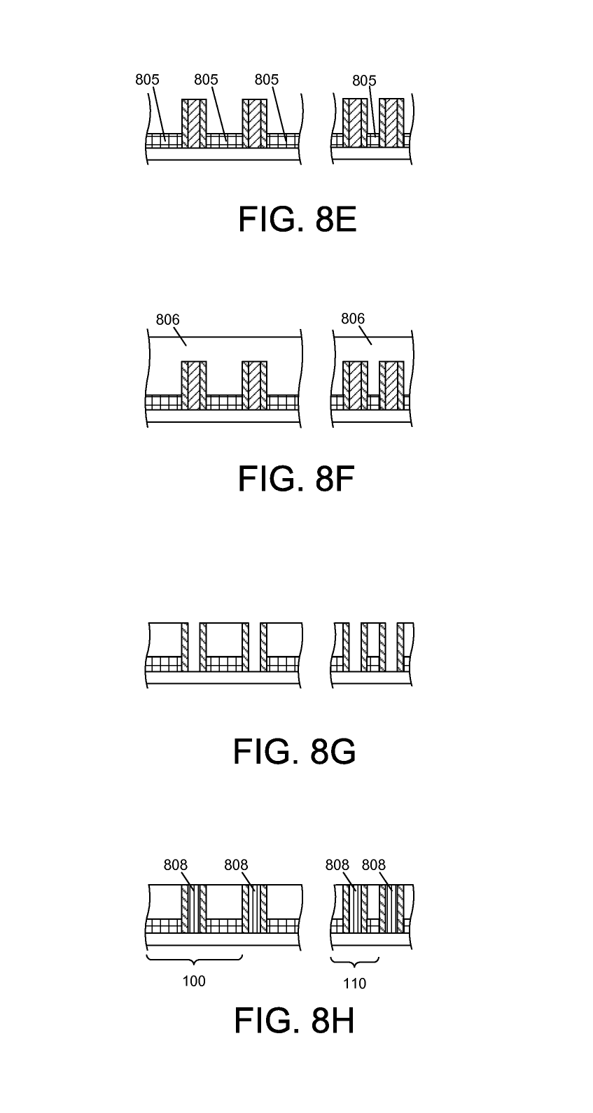

FIG. 7 depicts an exemplary embodiment of a method 700 to form FETs in a critical-speed path and FETs in a noncritical-speed path on the same chip according to the subject matter disclosed herein. FIGS. 8A-8H depict various stages of forming FETs in a critical-speed path and FETs in a noncritical-speed path on the same chip in accordance with exemplary embodiment of method 700. In FIGS. 8A-8H, the left side corresponds to a finFET at various stages of formation having a CPP that corresponds to a critical-speed path and the right side corresponds to a finFET at various stages of formation having a CPP that corresponds to a noncritical-speed path. As an exemplary illustration, the left side of FIGS. 8A-8H generally corresponds to FET 100 and the right side of generally corresponds to FET 110. In particular, the left side of FIGS. 8A-8H corresponds to a cross-sectional view taken, for example, along line A-A′ in FIG. 1A at various stages, and the right side corresponds to a cross-sectional view taken, for example, along line B-B′ in FIG. 1B at various stages.

At operation 701 in FIG. 7, poly-silicon mandrels 802 (FIG. 8A) are formed on a substrate 801 using well-known techniques generally having different widths and different pitches at selected regions based on the floorplan of a chip. Dummy patterns can be formed in pitch transition areas (for example, cells 401b in FIG. 4) between regions having different mandrel widths and pitches.

At operation 702, sidewall (SW) spacers 803 (FIG. 8B) are formed along the sides of the mandrels 802 using a well-known technique. The sidewall spacer length LSW can be selected based on whether the sidewall is being formed in a region having a relatively larger CCP or a relatively smaller CPP.

At operation 703, the mandrels 802 are selectively removed using a well-known technique. The sidewall spacers 803 remaining (FIG. 8C) will be used as a mask to define dummy gates of a first FET (left side) and a second FET (right side). The pitch for the dummy gate for the first FET is larger than the pitch of the dummy gate for the second FET. The dummy-gate length L_{DG} is substantially the same for the first FET and second FET.

At operation 704, sidewall spacers 804 (FIG. 8D) are formed along the dummy gates of the first and second FETs using a well-known technique.

At 705, merged source/drain (S/D) regions 805 (FIG. 8E) are formed for the first FET and the second FET using a well-known recess etch and epitaxial refill technique. The volume of recess and the volume of epitaxial refill associated with the recess region are larger for the first FET than for the second FET. The recess and refill of the S/D regions for the first and second FETs can be performed simultaneously or at different times, and can include different recess depths and profiles, different epitaxial refill materials, different material composition grading, different dopant grading, and the like. It is noted that the subject matter disclosed herein allows for a non-recess etch and epitaxial S/D growth process, if desired, in which the area and volume associated with the S/D region of the first FET is larger than for the second FET.

Alternatively, a blanket silicide layer could be formed on the structure, if desired, using a well-known silicide technique. The volume and/or depth of the salicide would be substantially the same or larger or different for the first FET, in part depending the size of the sidewall spacer formed in operation 704, and/or further dependent on whether the salicide formation is at the same or at different process steps, and whether the salicide formation is the same or different for the first FET.

At 706, an Inter-Layer Dielectric (ILD) layer 806 (FIG. 8F) is formed using a well-known technique.

At 707, a well-known chemical-mechanical planarization (CMP) technique is applied to the ILD layer and the dummy gate 803 is removed (FIG. 8G) using a well-known technique.

At 708, a replacement metal gate (RMG) region 808 (FIG. 8H) is formed using a well-known technique. Afterward, the contact regions are etched using a well-known technique, and metal contacts are formed on the S/D regions of the first and second FETs using a well-known technique. The cross-sectional area of the metal contact made to the S/D region of the first FET (left side, 100) is larger than the cross-sectional area of metal contact made to the S/D region of the second FET (right side, 110). In one exemplary embodiment, the spacing of the metal contact to the RMG region can be substantially the same or larger for the first FET (left side) in comparison to the spacing of the metal contact to the RMG region for the second FET (right side).

The etch of the contact regions and formation of the metal contact to the S/D regions of the first FET and second FET can be different, including the depth and volume of the etch of the contact region within the S/D regions for the first and second FET, and the subsequent volume of metal contact within the S/D regions for the first and second FET. The etch and metal contact deposition and fill can also be at the same or different steps and each can be different if desired for the first and second FET. Depending on the channel strain and R_{PARA} desired, and the depth and volume of salicide that may be formed at operation 705, the depth and volume of the metal contact material for the first FET may be greater than or less than the depth and volume of the metal contact material for the second FET. A chip is then formed using well-known techniques that includes within the same block critical-speed paths and noncritical-speed paths by forming desired connections between the FETs having different CPPs.

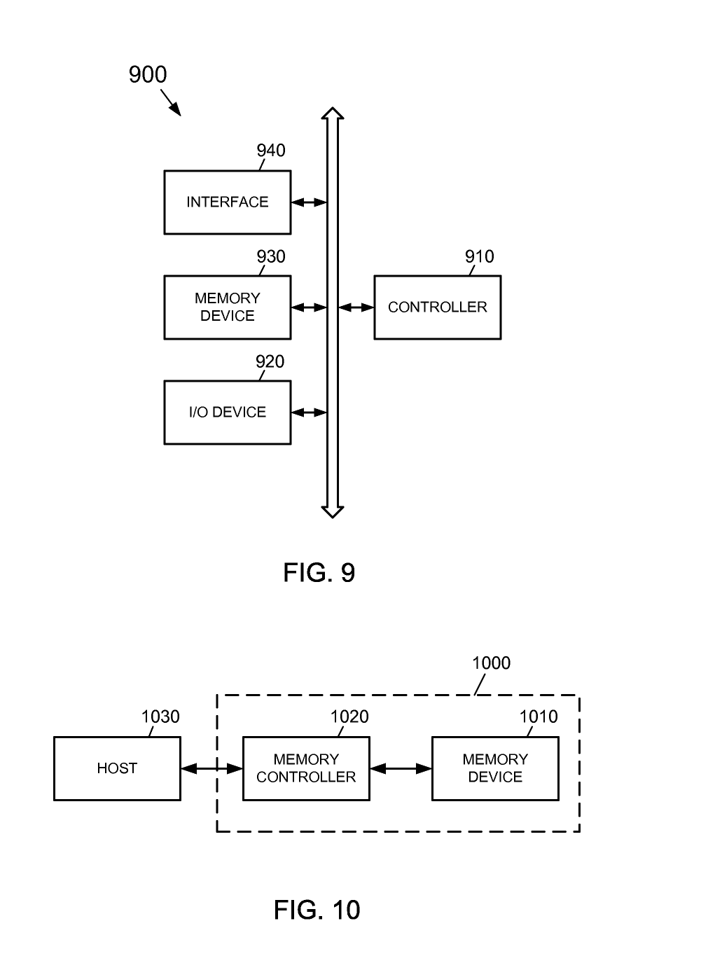

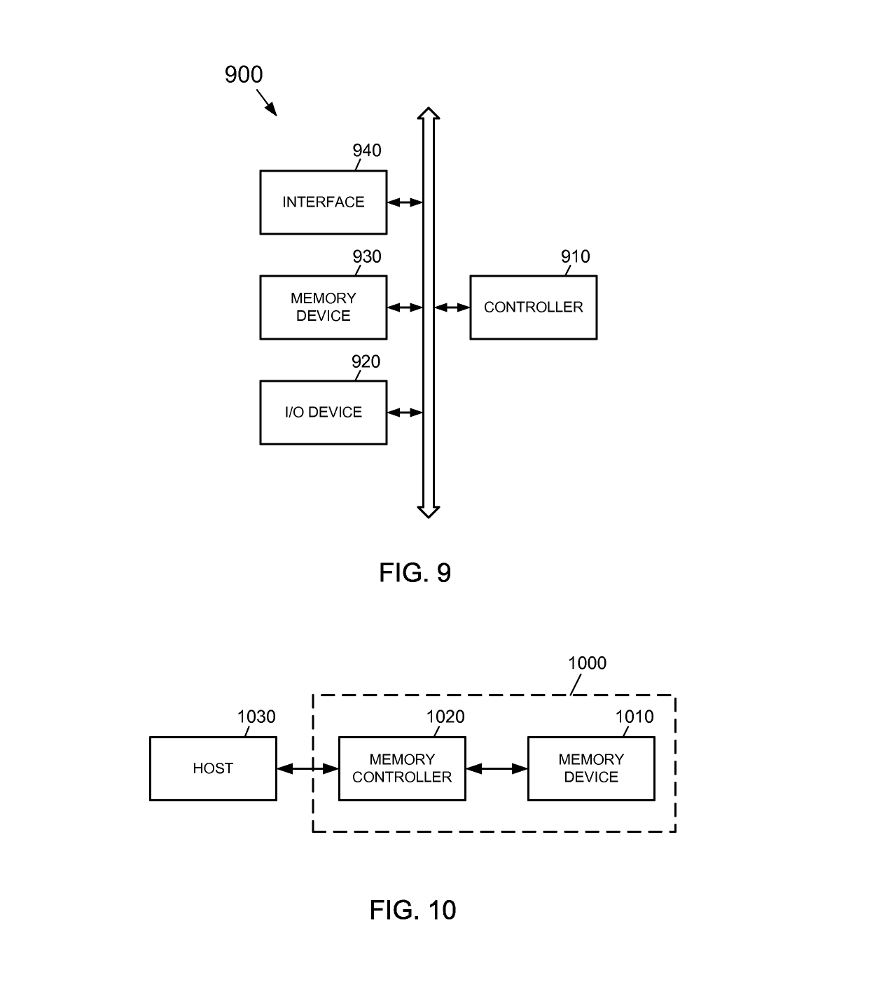

FIG. 9 depicts an electronic device 900 that comprises one or more integrated circuits (chips) comprising high-performance FETs formed in critical-speed paths in which the high-performance FETs have a contacted poly pitch (CPP) within the same block of the chip that is greater than the CPP of FETs in noncritical-speed paths according to exemplary embodiments disclosed herein. Electronic device 900 may be used in, but not limited to, a computing device, a personal digital assistant (PDA), a laptop computer, a mobile computer, a web tablet, a wireless phone, a cell phone, a smart phone, a digital music player, or a wireline or wireless electronic device. The electronic device 900 may comprise a controller 910, an input/output device 920 such as, but not limited to, a keypad, a keyboard, a display, or a touch-screen display, a memory 930, and a wireless interface 940 that are coupled to each other through a bus 950. The controller 910 may comprise, for example, at least one microprocessor, at least one digital signal process, at least one microcontroller, or the like. The memory 930 may be configured to store a command code to be used by the controller 910 or a user data. Electronic device 900 and the various system components comprising electronic device 900 may comprise one or more integrated circuits (chips) comprising high-performance FETs formed in critical-speed paths in which the high-performance FETs have a contacted poly pitch (CPP) within the same block of the chip that is greater than the CPP of FETs in noncritical-speed paths according to exemplary embodiments disclosed herein. The electronic device 900 may use a wireless interface 940 configured to transmit data to or receive data from a wireless communication network using a RF signal. The wireless interface 940 may include, for example, an antenna, a wireless transceiver and so on. The electronic system 900 may be used in a communication interface protocol of a communication system, such as, but not limited to, Code Division Multiple Access (CDMA), Global System for Mobile Communications (GSM), North American Digital Communications (NADC), Extended Time Division Multiple Access (E-TDMA), Wideband CDMA (WCDMA), CDMA2000, Wi-Fi, Municipal Wi-Fi (Muni Wi-Fi), Bluetooth, Digital Enhanced Cordless Telecommunications (DECT), Wireless Universal Serial Bus (Wireless USB), Fast low-latency access with seamless handoff Orthogonal Frequency Division Multiplexing (Flash-OFDM), IEEE 802.20, General Packet Radio Service (GPRS), iBurst, Wireless Broadband (WiBro), WiMAX, WiMAX-Advanced, Universal Mobile Telecommunication Service-Time Division Duplex (UMTS-TDD), High Speed Packet Access (HSPA), Evolution Data Optimized (EVDO), Long Term Evolution - Advanced (LTE-Advanced), Multichannel Multipoint Distribution Service (MMDS), and so forth.

FIG. 10 depicts a memory system 1000 that may comprise one or more integrated circuits (chips) comprising high-performance FETs formed in critical-speed paths in which the high-performance FETs have a contacted poly pitch (CPP) within the same block of the chip that is greater than the CPP of FETs in noncritical-speed paths according to example embodiments disclosed herein. The memory system 1000 may comprise a memory device 1010 for storing large amounts of data and a memory controller 1020. The memory controller 1020 controls the memory device 1010 to read data stored in the memory device 1010 or to write data into the memory device 1010 in response to a read/write request of a host 1030. The memory controller 1020 may include an address-mapping table for mapping an address provided from the host 1030 (e.g., a mobile device or a computer system) into a physical address of the memory device 1010. The memory device 1010 may comprise one or more semiconductor devices according to exemplary embodiments disclosed herein.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present inventive concept. Accordingly, all such modifications are intended to be included within the scope of the appended claims.

What is claimed is:

1. An integrated circuit, comprising:
at least one block comprising a first cell and a second cell, the first cell comprising a first Field Effect Transistor (FET) formed with a first contacted poly pitch (CPP), and the second cell comprising a second FET formed with a second CPP, the first CPP being greater than the second CPP.

2. The integrated circuit according to claim 1, wherein the first FET is part of a critical-speed path, and wherein the second FET is part of a noncritical-speed path, the critical-speed path operating at a faster speed than the noncritical-speed path.

3. The integrated circuit according to claim 1, wherein the first FET comprises a source/drain region having a first cross-sectional area and volume, and the second FET comprises a source/drain region having a second cross-sectional area and volume, the first cross-sectional area and volume being greater than the second cross-sectional area and volume.

4. The integrated circuit according to claim 1, wherein a gate length of the first FET is substantially the same as a gate length of the second FET.

5. The integrated circuit according to claim 1, wherein a channel strain of the first FET is greater than a channel strain of the second FET.

6. The integrated circuit according to claim 1, wherein a parasitic resistance of the first FET is less than a parasitic resistance of the second FET.

7. The integrated circuit according to claim 1, wherein a parasitic capacitance of the first FET is less than a parasitic capacitance of the second FET.

8. The integrated circuit according to claim 1, wherein the first FET comprises a planar FET, a finFET, a gate-all-around FET or a nanosheet FET, and
wherein the second FET comprises a planar FET, a finFET, a gate-all-around FET or a nanosheet FET.

9. An integrated circuit, comprising:
a critical-speed circuit path in a block of the integrated circuit, the critical-speed circuit path comprising a first Field Effect Transistor (FET) comprising a first contacted poly pitch (CPP); and
a noncritical-speed circuit path in the block of the integrated circuit, the noncritical-speed path comprising a second FET comprising a second CPP,
the first CPP being greater than the second CPP.

10. The integrated circuit according to claim 9, wherein the first FET comprises a source/drain region having a first cross-sectional area and volume, and the second FET comprises a source/drain region having a second cross-sectional area and volume, the first cross-sectional area and volume being greater than the second cross-sectional area and volume.

11. The integrated circuit according to claim 9, wherein a gate length of the first FET is substantially the same as a gate length of the second FET.

12. The integrated circuit according to claim 9, wherein a channel strain of the first FET is greater than a channel strain of the second FET.

13. The integrated circuit according to claim 9, wherein a parasitic resistance of the first FET is less than a parasitic resistance of the second FET.

14. The integrated circuit according to claim 9, wherein a parasitic capacitance of the first FET is less than a parasitic capacitance of the second FET.

15. The integrated circuit according to claim 9, wherein the first FET comprises a planar FET, a finFET, a gate-all-around FET or a nanosheet FET, and
wherein the second FET comprises a planar FET, a finFET, a gate-all-around FET or a nanosheet FET.

16. A method to form Field Effect Transistors (FETs) in a block of an integrated circuit, the method comprising:
forming a first FET in the block, the first FET comprising a first contacted poly pitch (CPP); and
forming a second FET in the block, the second FET comprising a second CPP,
the first CPP being greater than the second CPP.

17. The method according to claim 16, wherein the first FET is part of a critical-speed path, and wherein the second FET is part of a noncritical-speed path, the critical-speed path operating at a faster speed than the noncritical-speed path.

18. The method according to claim 16, further comprising:
forming a source/drain region for the first FET having a first cross-sectional area and volume; and
forming a source/drain region for the second FET having a second cross-sectional area and volume,
the first cross-sectional area and volume being greater than the second cross-sectional area and volume.

19. The method according to claim 16, wherein a parasitic resistance of the first FET is less than a parasitic resistance of the second FET.

20. The method according to claim 16, wherein a parasitic capacitance of the first FET is less than a parasitic capacitance of the second FET.
